(19) United States
(12) Patent Application Publication
(10) Pub. No.: US 2024/0012325 A1
(43) Pub. Date: Jan. 11, 2024

(54) METHOD TO OPTIMIZE POST DEPOSITION BAKING CONDITION OF PHOTO RESISTIVE MATERIALS

(71) Applicant: Applied Materials, Inc., Santa Clara, CA (US)

(72) Inventors: LUISA BOZANO, Los Altos Hills, CA (US); PAOLA DE CECCO, Salinas, CA (US); BEKELE WORKU, San Jose, CA (US); LAKMAL CHARIDU KALUTARAGE, San Jose, CA (US); RUIYING HAO, San Jose, CA (US)

(21) Appl. No.: 18/204,805

(22) Filed: Jun. 1, 2023

Related U.S. Application Data
(60) Provisional application No. 63/388,205, filed on Jul. 11, 2022.

(51) Int. Cl. G03F 7/004; H01L 21/67; G03F 7/16

(52) U.S. Cl. CPC G03F 7/0043; H01L 21/67225; G03F 7/168

(57) ABSTRACT

Embodiments disclosed herein include a method of optimizing a post deposition bake of a photoresist layer. In an embodiment, the method comprises depositing the photoresist layer on a substrate, baking the photoresist layer, and measuring properties of the photoresist layer with an optical tool.

### CROSS-REFERENCE TO RELATED APPLICATIONS

This application claims the benefit of U.S. Provisional Application No. 63/388,205, filed on Jul. 11, 2022, the entire contents of which are hereby incorporated by reference herein.

### BACKGROUND

### 1) Field

Embodiments of the present disclosure pertain to the field of semiconductor processing and, in particular, to methods of depositing a photoresist material and optimizing post apply bake (PAB) conditions to improve photoresist performance.

2) Description of Related Art

Lithography has been used in the semiconductor industry for decades for creating 2D and 3D patterns in microelectronic devices. The lithography process involves spin-on deposition of a film (photoresist), irradiation of the film with a selected pattern by an energy source (exposure), and removal (etch) of exposed (positive tone) or non-exposed (negative tone) region of the film by dissolving in a solvent. A bake may be carried out to drive off remaining solvent.

The photoresist should be a radiation sensitive material and upon irradiation a chemical transformation occurs in the exposed part of the film which enables a change in solubility between exposed and non-exposed regions. Using this solubility change, either exposed or non-exposed regions of the photoresist is removed (etched). The photoresist is then developed and the pattern can be transferred to the underlying thin film or substrate by etching. After the pattern is transferred, the residual photoresist is removed and repeating this process many times can give 2D and 3D structures to be used in microelectronic devices.

Several properties are important in lithography processes. Such important properties include sensitivity, resolution, lower line-edge roughness (LER), etch resistance, and ability to form thinner layers. When the sensitivity is higher, the energy required to change the solubility of the as-deposited film is lower. This enables higher efficiency in the lithographic process. Resolution and LER determine how narrow features can be achieved by the lithographic process. Higher etch resistant materials are required for pattern transferring to form deep structures. Higher etch resistant materials also enable thinner films. Thinner films increase the efficiency of the lithographic process.

### SUMMARY

Embodiments disclosed herein include a method of optimizing a post deposition bake of a photoresist layer. In an embodiment, the method comprises depositing the photoresist layer on a substrate, baking the photoresist layer, and measuring properties of the photoresist layer with an optical tool.

Embodiments may also comprise a method of optimizing a post apply bake (PAB) of a photoresist layer. In an embodiment, the method comprises depositing a first photoresist layer on a first substrate, baking the first photoresist layer with a first PAB, measuring a material property of the first photoresist layer during or after the first PAB with an optical tool, depositing a second photoresist layer on a second substrate, baking the second photoresist layer with a second PAB, measuring the material property of the second photoresist layer during or after the second PAB with the optical tool, and selecting the photoresist layer with the material property that provides the most desirable line width roughness, line edge roughness, and/or sensitivity to radiation exposure.

Embodiments may also include a semiconductor processing tool, that comprises a deposition module, where the deposition module is configured to deposit a photoresist layer on a substrate with a dry deposition process, a post apply bake (PAB) module, where the PAB module is configured to bake the photoresist layer, and an optical tool for measuring one or more properties of the photoresist layer during or after the bake.

### BRIEF DESCRIPTION OF THE DRAWINGS

FIG. 1 is a cross-sectional illustration of views representing various operations in a patterning process using a negative tone photoresist material formed by processes described herein, in accordance with an embodiment of the present disclosure.

FIG. 2 is a process flow diagram of a process for optimizing a post apply bake (PAB) of a photoresist layer in order to improve post exposure and develop properties of the photoresist layer, in accordance with an embodiment of the present disclosure.

FIG. 3 is an illustration of various microstructures of a resist in relation to increasing bake temperatures, in accordance with an embodiment of the present disclosure.

FIG. 4A is a graph of reflectance of a photoresist layer with and without a baking operation, in accordance with an embodiment of the present disclosure.

FIG. 4B is a graph of the extinction coefficient across different wavelengths for different PAB baking temperatures, in accordance with an embodiment of the present disclosure.

FIG. 4C is a graph of the thickness changes of the photoresist layer after different PAB baking temperatures, in accordance with an embodiment of the present disclosure.

FIG. 5A is a flow diagram depicting the process of developing a photoresist layer with different tools in order to generate a contrast curve in order to optimize performance of a photoresist layer, in accordance with an embodiment of the present disclosure.

FIG. 5B is a flow diagram depicting the process of analyzing optical properties of a photoresist layer within a single tool, in accordance with an embodiment of the present disclosure.

FIG. 6 is a cross-sectional illustration of a processing tool that is configured to deposit a photoresist layer and measure optical properties after a PAB, in accordance with an embodiment of the present disclosure.

FIG. 7 is an illustration of a block diagram of an exemplary computer system, in accordance with an embodiment of the present disclosure.

### DETAILED DESCRIPTION

Methods of optimizing the performance of a post apply bake (PAB) of a photoresist layer using in-situ or ex-situ optical measurement tools are described herein. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

To provide context, photoresist systems used in extreme ultraviolet (EUV) lithography suffer from low efficiency. That is, existing photoresist material systems for EUV lithography require high dosages in order to provide the needed solubility switch that allows for developing the photoresist material. Traditionally, carbon based films called organic chemically amplified photoresists (CAR) have been used as a photoresist. However, more recently organic-inorganic hybrid materials (metal-oxo) have been used as a photoresist with extreme ultraviolet (EUV) radiation. Such materials typically include a metal (such as Sn, Hf, Zr), oxygen, and carbon. Transformation from deep UV (DUV) to EUV in the lithographic industry facilitated narrow features with high aspect ratio. Metal-oxo based organic-inorganic hybrid materials have been shown to exhibit lower line edge roughness (LER) and higher resolution which are required for forming narrow features. Also, such films have higher sensitivity and etch resistance properties and can be implemented to fabricate relatively thinner films.

Currently, a metal-oxo photoresist is deposited by spin-on methods which includes wet chemistries. Post bake processes are required to drive off any remaining solvents from the film and to render the film stable. Also, wet methods can generate a lot of wet waste that the industry wants to move away from. Photoresist films deposited by spin-on methods often result in non-uniformity issues. In accordance with embodiments of the present disclosure, addressing one or more of the above issues, processes for vacuum deposition of a metal-oxo positive tone photoresist are described herein.

More particularly, embodiments disclosed herein include methods for optimizing the performance of photoresist films. The optimization relies on optical inspection of the film during and/or after the post apply bake (PAB). Material properties, such as, but not limited to, refractive index, dielectric constant, thickness, reflectance, and/or extinction coefficient can be used as a guide in order to select the optimal PAB conditions. Optical tools, such as reflectometry, ellipsometry, and other optical techniques can be used to predict and optimize the best temperature and duration that allows the photoresist film to rearrange and optimize its sensitivity to exposure of the patterning radiation. Additionally, correlations between optical properties and line width roughness and line edge roughness can also be used to further optimize the photoresist film. In a specific embodiment, the photoresist films may include metal-oxo photoresist systems, such as those described above. In other embodiments, the photoresist films may be any type of CAR material system.

In some embodiments, the optical inspection is implemented by an in-situ optical tool. An in-situ optical tool is integrated with the tool that is implementing the PAB process. In one embodiment, the PAB process is implemented in the same tool used to deposit the photoresist, For example, a resistive heater in the chuck may be used in order to bake the photoresist. An optical tool may be provided opposite from the chuck in order to measure one or more optical properties and/or thickness of the photoresist. Such an embodiment is particularly beneficial because the substrate (e.g., wafer or the like) does not need to be transferred between tools.

Additionally, embodiments disclosed herein allow for the optimization of the photoresist layer without the need to expose and develop the photoresist layer. The exposure and developing process is a particularly time intensive and costly process. In order to form the contrast curves typical of photoresist analysis, many substrates with photoresist layers need to be formed, exposed, and developed. Such a process is expensive. In embodiments disclosed herein, the optical properties and/or thickness of the photoresist layer can be used to identify trends that point towards more optimal PAB processes. Accordingly, the cost and duration of the photoresist layer optimization is significantly reduced.

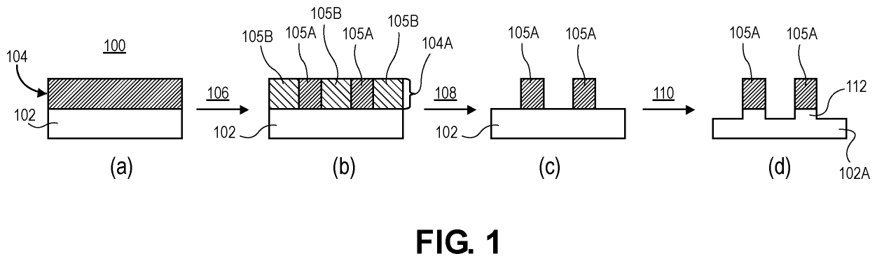

FIG. 1 illustrates cross-sectional views representing various operations in a patterning process using a negative tone photoresist material formed by processes described herein, in accordance with an embodiment of the present disclosure.

Referring to part (a) of FIG. 1, a starting structure 100 includes a negative tone photoresist layer 104 above a substrate or underlying layer 102. In one embodiment, the negative tone photoresist layer 104 is deposited using a dry deposition process. After the deposition process, a PAB may be implemented on the photoresist layer 104. The PAB may alter material properties of the photoresist layer 104 in order to improve performance of the subsequently developed photoresist layer 104.

Referring to part (b) of FIG. 1, the starting structure 100 is irradiated 106 in select locations to form an irradiated photoresist layer 104A having irradiated regions 105B and non-irradiated regions 105A. Referring to part (c) of FIG. 1, a removal or etch process 108 is used to provide a developed photoresist layer of non-irradiated regions 105A. Referring to part (d) of FIG. 1, an etch process 110 using the non-irradiated regions 105A as a mask is used to pattern the substrate or underlying layer 102 to form a patterned substrate or patterned underlying layer 102A including etched features 112.

Referring again to FIG. 1, the negative tone photoresist 104 is a radiation sensitive material and, upon irradiation, a chemical transformation occurs in the exposed part of the film which enables a change in solubility between exposed and non-exposed regions. Using the solubility change, exposed regions of the negative tone photoresist are removed (etched). The negative tone photoresist is then developed and the pattern can be transferred to the underlying thin film or substrate by etching. After the pattern is transferred, the residual negative tone photoresist is removed. The process can be repeated many times to fabricate 2D and 3D structures, e.g., for use in microelectronic devices.

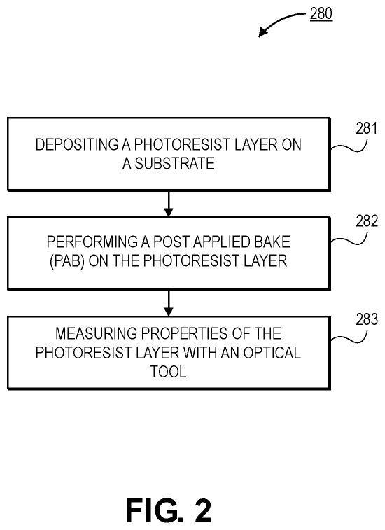

Referring now to FIG. 2, a process flow diagram of a process 280 for optimizing a photoresist film is shown, in accordance with an embodiment. In an embodiment, the process 280 may begin with operation 281, which comprises depositing a photoresist layer on a substrate. In an embodiment, the photoresist layer is deposited with a dry deposition process, such as an atomic layer deposition (ALD) process, a chemical vapor deposition (CVD) process, a plasma enhanced ALD (PE-ALD) process, or a plasma enhanced CVD (PE-CVD) process, or the like. While embodiments with dry deposition processes are described herein, it is to be appreciated that embodiments disclosed herein may also include the use of wet deposition processes. In a particular embodiment, the photoresist layer may be a metal-oxo photoresist layer. In other embodiments, the photoresist layer may include any CAR material system. In an embodiment, the substrate may be a wafer, such as a semiconductor wafer. For example, the substrate may be a silicon wafer with any suitable form factor (e.g., 300 mm, 450 mm, or the like).

In an embodiment, the process 280 may continue with operation 282, which comprises performing a PAB on the photoresist layer. The PAB process may include exposing the photoresist layer to an elevated temperature. For example, the temperature may be between 15° C. and 300° C. In a particular embodiment, the temperature may be between 50° C. and 250° C. In an embodiment, the duration of the PAB may be between thirty seconds and five minutes. The elevated temperature may be provided by any heating architecture. In some embodiments the chuck on which the substrate is supported may include a resistive heating element or the like. In other embodiments, one or more lamps may be used in order to heat the photoresist layer.

In an embodiment, the process 280 may continue with operation 283, which comprises measuring properties of the photoresist layer with an optical tool. In an embodiment, the optical tool may include single lamp reflectometry, dual lamp reflectometry, ellipsometry, or ultraviolet-visible spectrophotometry. In an embodiment, the properties may include one or more of a refractive index, a dielectric constant, a thickness, a reflectance, and/or an extinction coefficient. The different material properties may be correlated to properties of the photoresist layer, such as sensitivity to exposure radiation, line edge roughness, and line width roughness. That is, the measured material properties may not have a one-to-one relationship with sensitivity, line edge roughness, and line width roughness, but can be used in order to determine trends of the photoresist layer.

In an embodiment, operation 283 is implemented at the same time as the PAB. That is, changes to the photoresist layer can be determined in real time. Such an embodiment helps with determining the optimal duration of the PAB process. In an embodiment, operation 283 may be implemented after the PAB. Operation 283 may be implemented with an optical tool that is in-situ with the tool that executes that PAB. In other embodiments, operation 283 may be implemented with an optical tool that is ex-situ with the tool that executes the PAB.

In the particular embodiment described with process 280, a single substrate and photoresist layer are measured. However, it is to be appreciated that embodiments may include measuring the material properties of multiple photoresist layers on different substrates. For example, a first photoresist layer may be provided on a first substrate, and the first photoresist layer may be baked with a first PAB. Thereafter, a second photoresist layer may be provided on a second substrate, and the second photoresist layer may be baked with a second PAB. The second PAB may be different than the first PAB. The difference may include a different baking temperature and/or baking duration. As such, data can be obtained from a plurality of different PAB conditions in order to find the optimal PAB conditions.

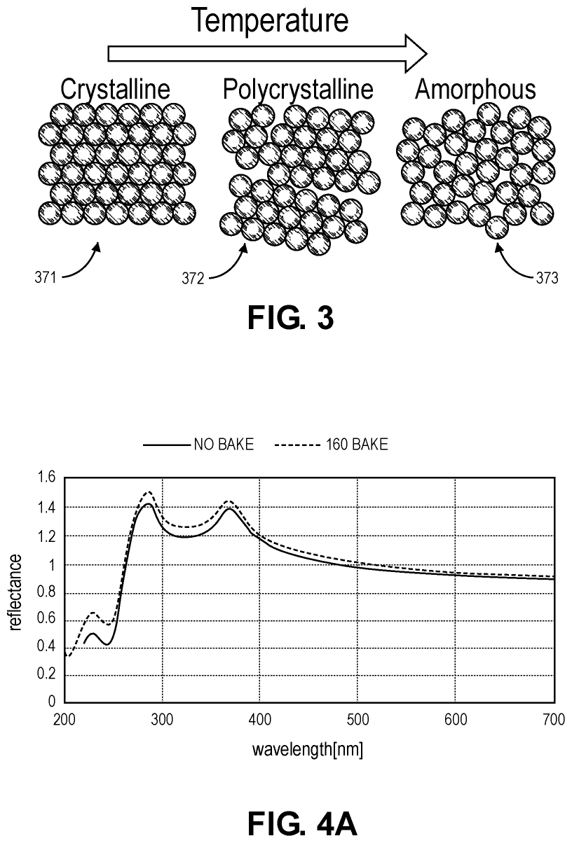

Referring now to FIG. 3, a schematic of the microstructure of the photoresist layer as temperature increases is shown, in accordance with an embodiment. As shown, at lower temperatures, the microstructure 371 of the photoresist layer may be substantially crystalline. At a medium temperature, the microstructure 372 may be polycrystalline, and at a high temperature the microstructure 373 may be amorphous. The different microstructures may allow for different properties of the photoresist layer. For example, different crystal structures may result in different radiation sensitivities, line edge roughness, and/or line width roughness. The microstructure of the photoresist layer may be determined in part by the optical properties of the photoresist film.

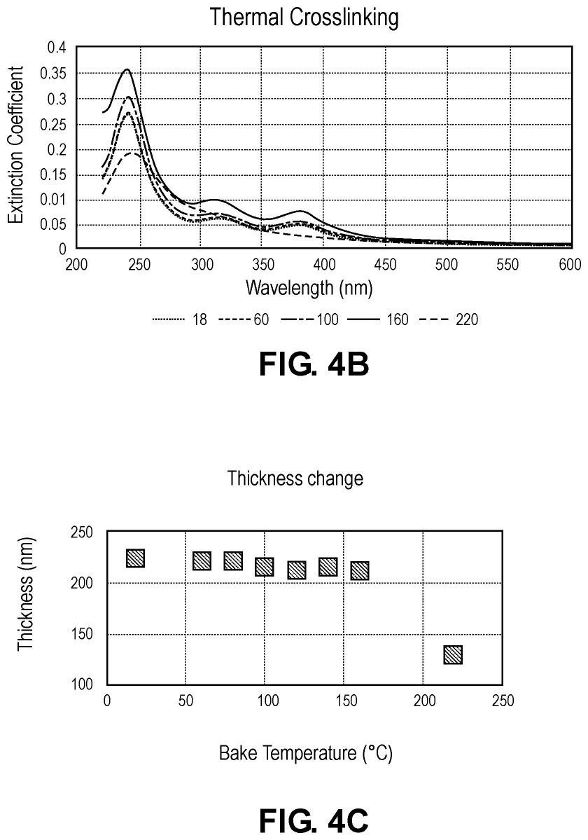

Referring now to FIG. 4A, a graph of the reflectance of a pair of photoresist layers is shown, in accordance with an embodiment. A first line illustrates the reflectance of a photoresist layer that has not been baked. In an embodiment, a second line illustrates the reflectance of a photoresist layer that has been baked. For example, the baking temperature may be approximately 160° C. As shown, the reflectance of the second photoresist layer is greater than the reflectance of the first photoresist layer. Particularly, the peaks of the second line are greater than the peaks of the first line.

Referring now to FIG. 4B, a graph of the extinction coefficient versus wavelength of a plurality of different baking temperatures is shown, in accordance with an embodiment. Of particular interest is the peak that is provided around 240 nm. As shown, the peak generally increases from PAB temperatures of 18° C. to 160° C., and there is a sharp decline in the peak at the PAB temperature of 220° C. As such, it can be determined that the optimal PAB temperature is between 160° C. and 220° C. The drop in extinction coefficient for the 220° C. line may be attributable to a change in the microstructure at relatively high temperatures.

Referring now to FIG. 4C, a graph of the thickness change at different bake temperatures is shown, in accordance with an embodiment. As shown, there is a small decrease in the thickness of the photoresist layers with increasing bake temperature up to 160° C. Thereafter, there is a significant decrease in the thickness for the bake temperature of 220° C.

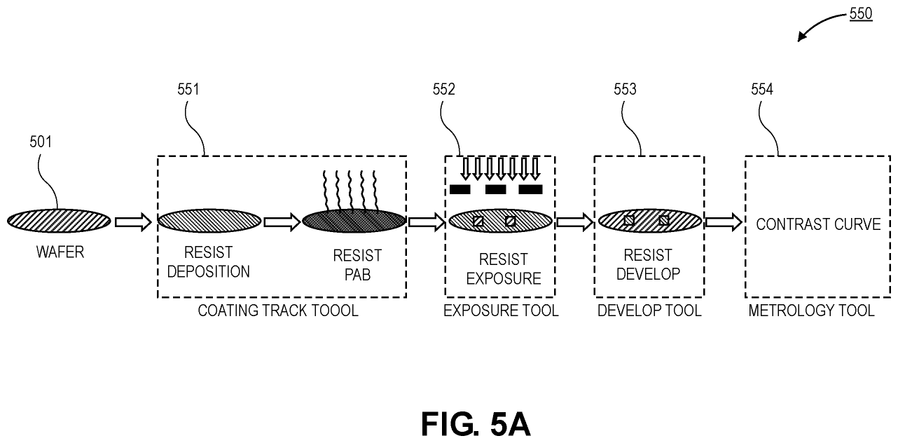

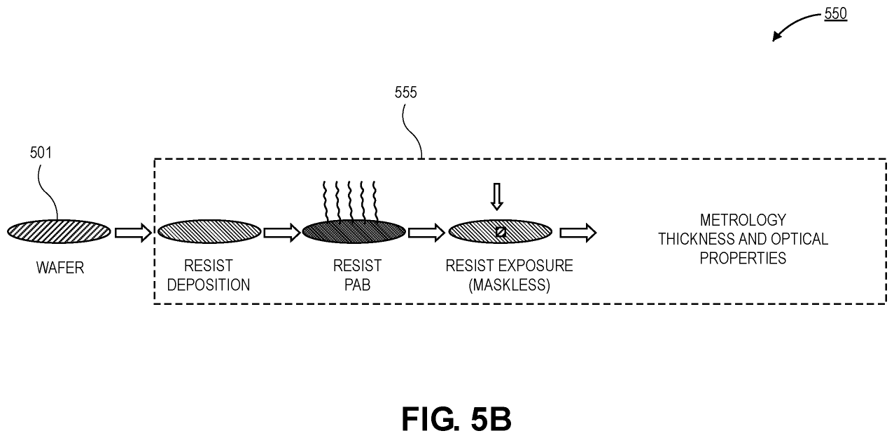

As noted above, existing processes for optimizing a PAB for a photoresist material is complex and expensive. An example of such a process is shown in FIG. 5A. As shown, a lithography system 550 is shown. In an embodiment, a wafer 501 is inserted into a coating track tool 551. In the tool 551, a photoresist layer is deposited on the wafer 501. The photoresist layer may then be baked with a resist PAB tool. In some embodiments, the deposition of the photoresist layer and the baking of the photoresist layer may be implemented in the same processing tool.

Thereafter, the wafer 501 is removed from the coating track tool 551 and inserted into an exposure tool 552. The exposure tool may be a DUV or EUV exposure tool. The exposure tool 552 may use a mask in order to selectively expose regions of the photoresist layer.

In an embodiment, the exposed wafer 501 is then moved to a develop tool 553 where the photoresist layer is developed. The process of exposing the photoresist layer and developing the photoresist layer is significantly time and cost intensive. Particularly, the exposure tool 552 is an expensive tool and generally has a low throughput.

After the photoresist layer is developed, the wafer may be provided into a metrology tool 554 in order to analyze the developed photoresist layer. In some embodiments, a contrast curve is used in order to determine the optimal PAB conditions of the photoresist layer. The contrast curve requires the exposure and development of a plurality of wafers. As such, the cost and time necessary to develop the contrast curve is high.

Accordingly, embodiments disclosed herein include an in-situ metrology tool so that the wafer dies not need to be passed between various tools. Additionally, the photoresist layer does not need to be exposed and patterned in some embodiments, As such, the cost and throughput of the photoresist layer optimization is improved.

As shown in FIG. 5B, a wafer 501 is inserted into a tool 555. In an embodiment, the tool 555 may include functionality to deposit a photoresist layer onto the wafer. For example, the photoresist layer may be deposited with a dry deposition process or a wet deposition process (e.g., spin coating). In an embodiment, the photoresist layer may then be baked with a PAB process. The baking process may use a resistive heater on the chuck or one or more lamps opposite from the chuck. In some embodiments, the tool 555 may further comprise an exposure apparatus. In contrast to the embodiment shown in FIG. 5A, the exposure process may be a maskless exposure process, such as electron beam lithography.

In an embodiment, the tool 555 may further comprise an in-situ metrology tool. The metrology tool may include an optical metrology tool such as, single lamp reflectometry, dual lamp reflectometry, ellipsometry, or ultraviolet-visible spectrophotometry. The metrology tool may provide thickness measurements and/or optical properties of the photoresist layer. For example, graphs similar to those shown in FIGS. 4A-4C may be generated with the in-situ metrology tool.

Particularly, it is noted that the photoresist layer does not need to be developed in order to perform the metrology. In some embodiments, the photoresist layer may not be exposed either. This improves throughput and allows for more PAB conditions to be analyzed. As such, optimal photoresist PAB conditions can be obtained at a lower cost and within a reduced period of time. Additionally, since the tool 555 is self-contained, there is no need to transfer the wafer 501 between different tools, as is the case in the embodiment shown in FIG. 5A.

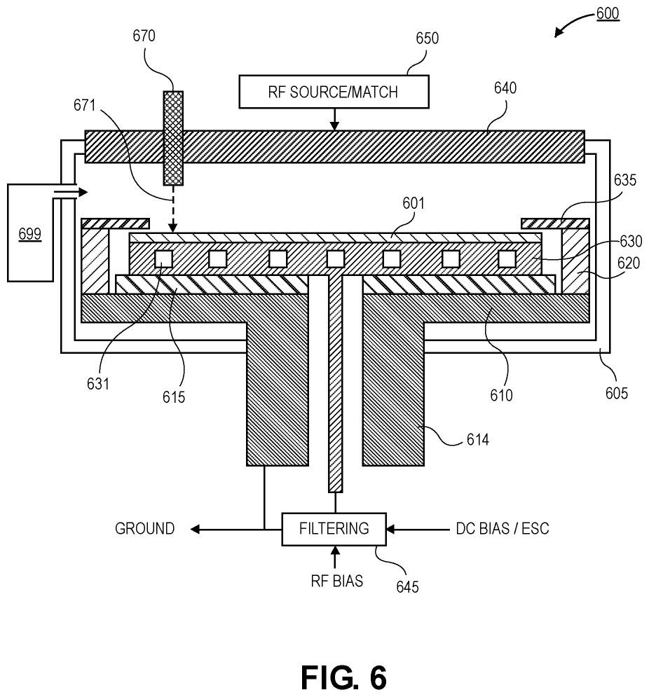

Referring now to FIG. 6, a cross-sectional illustration of a processing tool 600 is shown, in accordance with an embodiment. In an embodiment, the processing tool 600 may include a chamber 605. The chamber 605 may be any suitable chamber capable of supporting a sub-atmospheric pressure (e.g., a vacuum pressure). In an embodiment, an exhaust (not shown) that includes a vacuum pump may be coupled to the chamber 605 to provide a sub-atmospheric pressure. In an embodiment, a lid may seal the chamber 605. For example, the lid may include a showerhead assembly 640 or the like. The showerhead assembly 640 may include fluidic pathways to enable processing gasses and/or inert gasses to be flown into the chamber 605. In some embodiments where the processing tool 600 is suitable for plasma enhanced operation, the showerhead assembly 640 may be electrically coupled to an RF source and matching circuitry 650. In yet another embodiment, the tool 600 may be configured in an RF bottom fed architecture. That is, the pedestal 630 is connected to an RF source, and the showerhead assembly 640 is grounded. In such an embodiment, the filtering circuitry may still be connected to the pedestal. In one embodiment, a precursor gas is stored in an ampoule 699.

In an embodiment, an optical metrology tool 670 is provided through the lid 640. The optical metrology tool 670 may include one or more of a single lamp reflectometry tool, a dual lamp reflectometry tool, an ellipsometry tool, or an ultraviolet-visible spectrophotometry tool. While shown as passing through the lid 640, it is to be appreciated that the optical metrology tool 670 may be provided through any component of the processing tool 600 that allows for measurements of the photoresist layer on the wafer 601. For example, light 671 may be directed to the wafer 601 and reflected back to the optical metrology tool 670. Particularly, it is to be appreciated that the optical metrology tool 670 is provided as an in-situ tool. Therefore, the wafer 601 does not need to be transported to another chamber in order to execute the metrology necessary in order to optimize PAB conditions.

In an embodiment, a displaceable column for supporting a wafer 601 is provided in the chamber 605. In an embodiment, the wafer 601 may be any substrate on which a photoresist material is deposited. For example, the wafer 601 may be a 300 mm wafer or a 450 mm wafer, though other wafer diameters may also be used. Additionally, the wafer 601 may be replaced with a substrate that has a non-circular shape in some embodiments. The displaceable column may include a pillar 614 that extends out of the chamber 605. The pillar 614 may have a port to provide electrical and fluidic paths to various components of the column from outside the chamber 605.

In an embodiment, the column may include a baseplate 610. The baseplate 610 may be grounded. The baseplate 610 may include fluidic channels to allow for the flow of an inert gas to provide an edge purge flow. In an embodiment, an insulating layer 615 is disposed over the baseplate 610. The insulating layer 615 may be any suitable dielectric material. For example, the insulating layer 615 may be a ceramic plate or the like. In an embodiment, a pedestal 630 is disposed over the insulating layer 615. The pedestal 630 may include a single material or the pedestal 630 may be formed from different materials. In an embodiment, the pedestal 630 may utilize any suitable chucking system to secure the wafer 601. For example, the pedestal 630 may be a vacuum chuck or a monopolar chuck. In embodiments where a plasma is not generated in the chamber 605, the pedestal 630 may utilize a bipolar chucking architecture.

The pedestal 630 may include a plurality of cooling channels 631. The cooling channels 631 may be connected to a fluid input and a fluid output (not shown) that pass through the pillar 614. In an embodiment, the cooling channels 631 allow for the temperature of the wafer 601 to be controlled during operation of the processing tool 600. For example, the cooling channels 631 may allow for the temperature of the wafer 601 to be controlled to between approximately −40° C. and approximately 200° C. In an embodiment, the pedestal 630 may also comprise a resistive heating element (not shown). The resistive heating element may be used in order to set a PAB baking temperature for the wafer 601. In a particular embodiment, the PAB baking temperature may be provided between approximately 15° C. and 250° C. The resistive heating element allows for the wafer 601 and the photoresist layer to be heated to a particular temperature for a desired duration. The optical metrology tool 670 may measure optical and/or thickness properties of the photoresist layer on the wafer 601. The optical metrology may be implemented during the PAB process or after the PAB process. In an embodiment, the pedestal 630 connects to the ground through filtering circuitry 645, which enables DC and/or RF biasing of the pedestal with respect to the ground.

In an embodiment, an edge ring 620 surrounds a perimeter of the insulating layer 615 and the pedestal 630. The edge ring 620 may be a dielectric material, such as a ceramic. In an embodiment, the edge ring 620 is supported by the base plate 610. The edge ring 620 may support a shadow ring 635. The shadow ring 635 has an interior diameter that is smaller than a diameter of the wafer 601. As such, the shadow ring 635 blocks the photoresist from being deposited onto a portion of the outer edge of the wafer 601. A gap is provided between the shadow ring 635 and the wafer 601. The gap prevents the shadow ring 635 from contacting the wafer 601, and provides an outlet for the edge purge flow. In an embodiment, a dual channel showerhead can be used for a positive tone photoresist fabrication process.

While the shadow ring 635 provides some protection of the top surface and edge of the wafer 601, processing gasses may flow/diffuse down along a path between the edge ring 620 and the wafer 601. As such, embodiments disclosed herein may include a fluidic path between the edge ring 620 and the pedestal 630 to enable an edge purge flow. Providing an inert gas in the fluidic path increases the local pressure in the fluidic path and prevents processing gasses from reaching the edge of the wafer 601. Therefore, deposition of the photoresist is prevented along the edge of the wafer 601.

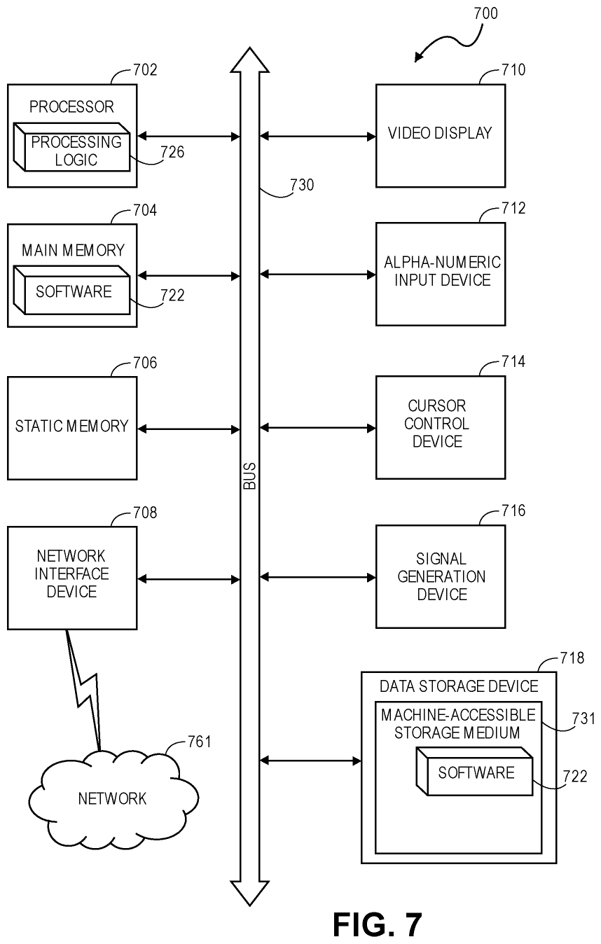

FIG. 7 illustrates a diagrammatic representation of a machine in the exemplary form of a computer system 700 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 700 includes a processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), MRAM, etc.), and a secondary memory 718 (e.g., a data storage device), which communicate with each other via a bus 730.

Processor 702 represents one or more general-purpose processing devices such as a microprocessor, central processing unit, or the like. More particularly, the processor 702 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 702 may also be one or more special-purpose processing devices such as an application specific integrated circuit (ASIC), a field programmable gate array (FPGA), a digital signal processor (DSP), network processor, or the like. Processor 702 is configured to execute the processing logic 726 for performing the operations described herein.

The computer system 700 may further include a network interface device 708. The computer system 700 also may include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium (or more specifically a computer-readable storage medium) 732 on which is stored one or more sets of instructions (e.g., software 722) embodying any one or more of the methodologies or functions described herein. The software 722 may also reside, completely or at least partially, within the main memory 704 and/or within the processor 702 during execution thereof by the computer system 700, the main memory 704 and the processor 702 also constituting machine-readable storage media. The software 722 may further be transmitted or received over a network 720 via the network interface device 708.

While the machine-accessible storage medium 732 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

In accordance with an embodiment of the present disclosure, a machine-accessible storage medium has instructions stored thereon which cause a data processing system to perform a method of forming a positive tone photoresist layer over a substrate in a vacuum chamber. The method includes providing a metal precursor vapor into the vacuum chamber. The method also includes providing an oxidant vapor into the vacuum chamber. A reaction between the metal precursor vapor and the oxidant vapor results in the formation of a positive tone photoresist layer on a surface of the substrate.

Thus, methods for forming a positive tone photoresist using dry processes have been disclosed.

What is claimed is:

1. A method of optimizing a post deposition bake of a photoresist layer, comprising:
depositing the photoresist layer on a substrate;
baking the photoresist layer; and
measuring properties of the photoresist layer with an optical tool.

2. The method of claim 1, wherein the optical tool comprises single lamp reflectometry, dual lamp reflectometry, ellipsometry, or ultraviolet-visible spectrophotometry.

3. The method of claim 1, wherein the optical tool uses electromagnetic radiation that is between 200 nm and 800 nm.

4. The method of claim 1, wherein properties of the photoresist layer include a refractive index, a dielectric constant, a thickness, a reflectance, and/or an extinction coefficient.

5. The method of claim 4, wherein the properties correlate to a microstructure of the photoresist layer.

6. The method of claim 1, wherein measuring properties of the photoresist layer is done after the baking.

7. The method of claim 6, wherein the optical tool is a distinct tool apart from a tool used to bake the photoresist layer.

8. The method of claim 1, wherein measuring properties of the photoresist layer is done during the baking.

9. The method of claim 8, wherein the optical tool is in-situ with a tool used for the baking.

10. The method of claim 1, wherein the properties are correlated to one or more of line width roughness, line edge roughness, and sensitivity to radiation exposure.

11. The method of claim 1, wherein the photoresist layer is a metal oxo photoresist material.

12. The method of claim 1, wherein the photoresist layer is a chemically amplified resist (CAR).

13. A method of optimizing a post apply bake (PAB) of a photoresist layer, comprising:
depositing a first photoresist layer on a first substrate;
baking the first photoresist layer with a first PAB;
measuring a material property of the first photoresist layer during or after the first PAB with an optical tool;
depositing a second photoresist layer on a second substrate;
baking the second photoresist layer with a second PAB;
measuring the material property of the second photoresist layer during or after the second PAB with the optical tool; and
selecting the photoresist layer with the material property that provides the most desirable line width roughness, line edge roughness, and/or sensitivity to radiation exposure.

14. The method of claim 13, wherein the first PAB and the second PAB are at different temperatures.

15. The method of claim 13, wherein the first PAB and the second PAB have different durations.

16. The method of claim 13, wherein the optical tool is integrated with the tool that implements the PAB.

17. The method of claim 13, wherein the PAB is optimized without exposing and developing the first photoresist layer or the second photoresist layer.

18. A semiconductor processing tool, comprising:
a deposition module, wherein the deposition module is configured to deposit a photoresist layer on a substrate with a dry deposition process;
a post apply bake (PAB) module, wherein the PAB module is configured to bake the photoresist layer; and
an optical tool for measuring one or more properties of the photoresist layer during or after the bake.

19. The semiconductor processing tool of claim 18, wherein the optical tool comprises single lamp reflectometry, dual lamp reflectometry, ellipsometry, or ultraviolet-visible spectrophotometry.

20. The semiconductor processing tool of claim 18, wherein the dry deposition process includes atomic layer deposition (ALD), plasma enhanced ALD (PE-ALD), chemical vapor deposition (CVD), or plasma enhanced CVD (PE-CVD).
